(19) United States
(12) Patent Application Publication
(10) Pub. No.: US 2024/0026527 A1
(43) Pub. Date: Jan. 25, 2024

(54) METHOD OF DEPOSITING SILICON BASED DIELECTRIC FILM

(71) Applicant: Applied Materials, Inc., Santa Clara, CA (US)

(72) Inventors: Geetika BAJAJ, Cupertino, CA (US); Supriya GHOSH, San Jose, CA (US); Susmit Singha ROY, Campbell, CA (US); Darshan THAKARE, Thane West (IN); Gopi Chandran RAMACHANDRAN, Mumbai (IN); Bhaskar Jyoti BHUYAN, San Jose, CA (US); Abhijit B. MALLICK, Fremont, CA (US)

(73) Assignee: Applied Materials, Inc., Santa Clara, CA (US)

(21) Appl. No.: 18/224,455

(22) Filed: Jul. 20, 2023

Related U.S. Application Data
(60) Provisional application No. 63/369,134, filed on Jul. 22, 2022.

(51) Int. Cl. C23C 16/04; C23C 16/30; C23C 16/56

(52) U.S. Cl. CPC C23C 16/045; C23C 16/30; C23C 16/56

(57) ABSTRACT

A method of forming a high aspect ratio structure within a 3D NAND structure is provided. The method includes delivering a precursor to a high aspect ratio opening disposed within a multilayer stack having two or more alternating layers. The precursor is selected from the group consisting of a diaminosilane, an aminosilane, and a combination thereof. The method includes delivering an oxygen-containing compound to the high aspect ratio opening. The precursor and the oxygen-containing compound are alternated cyclically to fill the high aspect ratio opening.

### CROSS-REFERENCE TO RELATED APPLICATIONS

This application claims benefit of U.S. provisional patent application Ser. No. 63/369,134, filed Jul. 22, 2022, which is herein incorporated by reference.

### BACKGROUND

### Field

Embodiments of the present disclosure generally relate to a chemistry and method of forming high aspect ratio features that are substantially free of voids and seams.

### Description of the Related Art

Memory devices achieve increased capacity by density scaling which involves stacking memory cells vertically in layers. These high aspect ratio structures pose various processing challenges particular in large area gap fill. Currently, large area gap fill is done using plasma enhanced chemical vapor deposition processes to deposit silicon-containing films. Conventional PECVD processes tend to create seam and void challenges in addition to conformality challenges. The silicon-containing films are subsequently etched to form memory openings which are filled with conductive metals to form connections. Forming the connections can cause cracking and other defects which can be problematic in downstream processes.

Therefore there is a need for large area gap fill processes and chemistry that enables high throughput and high quality devices having structure that are substantially free of voids and seams.

### SUMMARY

In some embodiments, a method of forming a high aspect ratio structure within a 3D NAND structure is provided. The method includes delivering a precursor to a high aspect ratio opening disposed within a multilayer stack having two or more alternating layers. The precursor is selected from the group consisting of a diaminosilane, an aminosilane, and a combination thereof. The method includes delivering an oxygen-containing compound to the high aspect ratio opening. The precursor and the oxygen-containing compound are alternated cyclically to fill the high aspect ratio opening.

In some embodiments, a method of forming a 3D NAND structure is provided. The method includes delivering a precursor to a high aspect ratio opening disposed within a multilayer stack having two or more alternating layers. The precursor is selected from the group consisting of a diaminosilane, an aminosilane, and a combination thereof. The method includes delivering an oxygen-containing plasma to the high aspect ratio opening. The precursor and the oxygen-containing plasma are alternated cyclically to fill the high aspect ratio opening with a silicon-containing material. The method includes etching an opening within the silicon-containing material.

In some embodiments, a method of forming a 3D NAND structure on a substrate is provided. The method includes delivering a precursor to a high aspect ratio opening disposed within a multilayer stack having two or more alternating layers, the precursor comprises a diaminosilane. The method includes delivering an oxygen-containing plasma to the high aspect ratio opening. The precursor and the oxygen-containing plasma are alternated cyclically to fill the high aspect ratio opening with a silicon-containing material. The high aspect ratio opening includes an aspect ratio of about 10:1 or greater.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts a process flow diagram of a method according to some embodiments described herein.

FIG. 2 depicts a memory device having a staircase structure prior to depositing a gap fill material, according to some embodiments described herein.

FIG. 3 depicts a first view of a memory device having a staircase structure and a gap fill material, according to some embodiments described herein.

FIG. 4 depicts a second view of a memory device having a staircase structure and a gap fill material, according to some embodiments described herein.

FIG. 5 depicts a memory device having a staircase structure, a gap fill material, and memory openings, according to some embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Recently, high density storage devices have been developed that include a three-dimensional (3D) stacked memory structure. For example, a 3D NAND stacked memory device can be formed from an array of alternating vertical stacks of dielectric materials and electrically conductive layers (e.g., tungsten containing layers). A staircase structure can be formed with the alternating vertical stacks of dielectric materials using etch methods. A large area, high aspect ratio opening is formed during the etch methods used for forming the staircase structure. In some embodiments, the large area, high aspect ratio opening has a depth of about 10 μm to about 15 μm and a width of about 1 μm to about 2 μm. In some embodiments, the aspect ratio of the opening is about 5:1 to about 50:1, such as about 10:1 to about 20:1. The high aspect ratio opening is filled with a dielectric material, such as a silicon-containing material.

Memory openings are formed and extend vertically through the silicon-containing material and the dielectric material containing layers in the alternating stack to expose portions of the conductive layers. The memory openings have varying depths within the alternating stack structure. The memory openings are eventually filled with a conductive material to form a connection with the exposed portion of each conductive layer in each layer of the alternating stack. The electrically conductive layers within the alternating stack can function as word lines of a 3D NAND stacked memory device, and bit lines overlying an array of memory stack structures can be connected to drain-side ends of the semiconductor channels. During etching and filling the memory openings with the conductive material, cracks and defects may form along the connection, particularly at the bottom and top of the connection. Without being bound by theory, it is believed that the cracks and defects may be formed if the silicon-containing material has tensile stress. It has been discovered that depositing the silicon-containing material using the processes described herein provides a large area gap fill that has compressive stress. The compressive property of the silicon-containing material enables formation of memory openings and formation of connections without cracking.

Additionally, filling large areas (e.g., large area gap fill) with the silicon-containing material can form voids and seams which can cause quality issues for memory devices in downstream processing, such as cracking and shrinking. The processes described herein optimizes large area gap fill while reducing potential of shrinkage and stress, as well has enhancing film quality. The methods described herein deposits silicon-containing material, such as silicon based dielectric films using a diaminosilane precursor, an aminosilane precursor, or combinations thereof in an atomic layer deposition process. In particular, 3DNAND structures can be formed by stacking alternating films and forming channels through the stack of alternating films. Conventional methods of filling the high aspect ratio openings with a silicon-containing material includes using plasma enhanced chemical vapor deposition (PECVD) processes. The film deposited in a conventional manner typically has a tensile property which causes cracking in the device after subsequent processing, such as during etching and metal connection formation. It has been discovered that the chemistry and use of atomic layer deposition (ALD) described herein enables deposition of film having compressive properties and less prone to cracking. The resulting device maintains structural integrity after further processing.

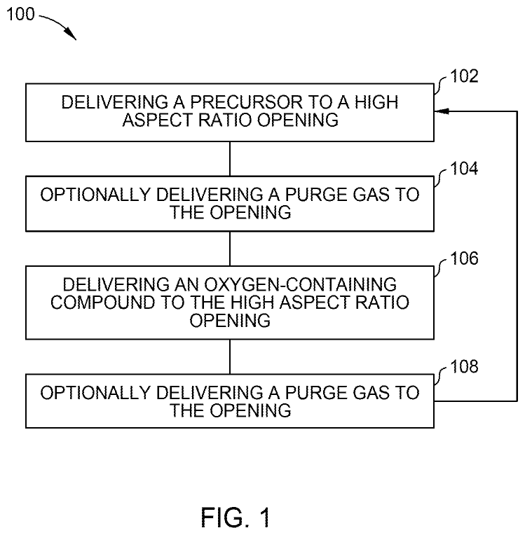

FIG. 1 depicts a process flow diagram of an example method 100 according to some embodiments. The method 100 includes, in operation 102, delivering a precursor to a high aspect ratio opening. The precursor includes diaminosilane, an aminosilane, or a combination thereof. The precursor is pulsed for about 200 milliseconds (ms) to about 1200 ms, such as about 400 ms to about 1000 ms. In some embodiments, the precursor is flowed at a rate of about 350 mg/m to about 1400 mg/m, such as about 400 mg/m to about 1200 mg/m, such as about 500 mg/m to about 1000 mg/m, such as about 600 mg/m to about 800 mg/m. In some embodiments, the precursor is delivered as a mixture with a carrier gas, such as argon gas. A total flow of the mixture is about 1500 sccm to about 2500 sccm, such as about 1700 sccm to about 2300 sccm. The temperature of the substrate is maintained at about 350° C. to about 650° C., such as about 450° C. to about 550° C. The pressure is about 2 torr to about 10 torr, such as about 4 torr to about 8 torr. As used herein, all flow rates and process conditions provided are for chambers processing substrates having substrate diameters of about 300 nm. Other process condition ranges are also contemplated which can be scaled to other process chamber sizes.

In operation 106, the method includes delivering an oxygen-containing compound to the high aspect ratio opening. In some embodiments, the oxygen-containing compound is an oxygen-containing plasma that is delivered from a remote plasma source. An oxygen (O₂) gas is provided to the remote plasma source at a flow rate of about 1000 sccm to about 3000 sccm, such as about 1500 sccm to about 2500 sccm, such as about 2000 sccm to about 2250 sccm. In some embodiments, a carrier gas is delivered to the high aspect ratio opening at a rate of about 0 sccm to about 3000 sccm, such as about 100 sccm to about 2000 sccm, such as about 500 sccm to about 1000 sccm. It has been discovered that delivering the oxygen-containing compound from the remote plasma source improves film quality and reduces seams within the filled opening. The oxygen-containing compound can include 03 (e.g., ozone), H₂O₂ (e.g., peroxide), oxygen plasma, or combinations thereof.

In some embodiments, the oxygen-containing compound is pulsed for about 2 seconds to about 10 seconds, such as about 2 seconds to about 8 seconds, such as about 4 seconds to about 6 seconds. In some embodiments, a time pulse ratio of precursor to oxygen-containing plasma is about 1:100 to about 1:2, such as about 1:20 to about 1:5, such as about 1:12 to about 1:8, such as about 1:10 to about 1:7. A power source coupled to the remote plasma source energizes gas delivered to the remote plasma source at a power of about 100 W to about 300 W, such as about 200 W to about 250 W, and a frequency of about 2 MHz to about 60 MHz, such as about 13 MHz to about MHz, such as 13.56 MHz or about 27 MHz, or about 40 MHz, or about 60 MHz. It has been discovered that tuning the power and frequency applied to the plasma, such as using an increased power and frequency during treatment and oxidation enables filling the high aspect ratio openings with a gap fill that is substantially free of voids and substantially free of seams. Without being bound by theory, it is believed that increasing power and frequency generations more radicals needed for the reaction to deposit the film, a concentration of radicals can be increased in order to increase growth per cycle of the deposited, such as when growth per cycle begins to decrease.

Operations 102 and 106 are alternated cyclically to fill the high aspect ratio opening, such as in an atomic layer deposition process. The method 100 can be combined with a PECVD process to increase a gap fill rate of the opening. In some embodiments, about 10% to about 50% of the total thickness of the gap fill for the opening is deposited using PECVD, such as about 20% to about 30% followed by the remaining thickness using ALD deposition. The method 100 can be used in any high aspect ratio openings for a variety of semiconductor devices. In some embodiments, a purge gas is supplied to the opening between each pulse, in optional operations 104, 108. The purge gas can be a nonreactive gas, such as a nitrogen-containing gas (e.g., diatomic nitrogen), an argon-containing gas (e.g., argon), or combinations thereof. As used herein, a process cycle includes operations 102, 106, and optional operations 104, 108 between each operation of 102 and 106. The process described herein provides a film deposition growth per cycle of about 1.5 Å per cycle to about 3 Å per cycle, such as about 1.75 Å per cycle to about 2.25 Å per cycle. In some embodiments, the substrate is maintained at a temperature of about 100° C. to about 450° C., such as about 150° C. to about 350° C., such as about 200° C. to about 325° C. during one or more of the operations 102, 104, 106, 108. In some embodiments, the chamber is maintained at a pressure of about 2 torr to about 10 torr, such as about 4 torr to about 8 torr. Without being bound by theory, it is believed that increasing the temperature of the substrate increases a compressive strength of the deposited silicon-containing gap fill material.

In some embodiments, the deposited film (e.g., gap fill material) has a film conformality of about 98% to about 100%. In some embodiments, the deposited film has a shrinkage of less than 15%, such as about 0.1% to about 5%, such as about 1% to about 3%, or about 7% to about 10%. As used herein, “shrinkage” refers to a percent decrease in a dimension, such as width or thickness, of a film as-deposited after annealing at a temperature of about 850° C. for about 1 hour. Shrinkage can be measured at a horizontal and/or vertical direction.

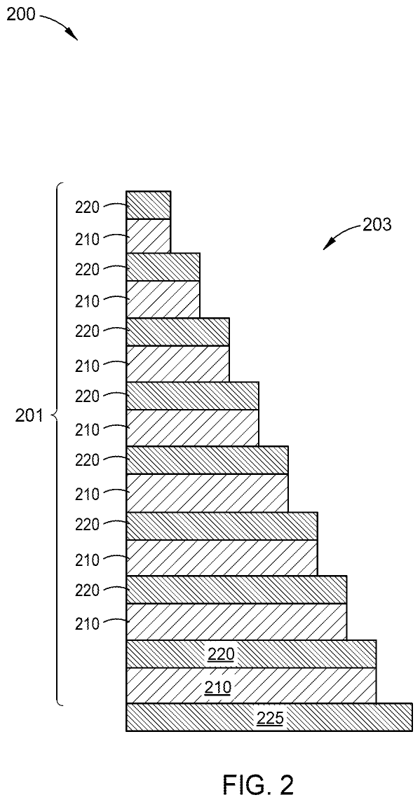

FIG. 2 depicts a memory device having a staircase structure 200 prior to depositing a gap fill material (e.g., silicon-containing material), according to some embodiments described herein. In some embodiments, the substrate 225 includes a multilayer stack 201 that includes a plurality of conductive layers 220 and a plurality of intervening dielectric material layers disposed therebetween. In some embodiments, the multilayer stack 201 includes about 100 layers or more, such as about 150 layers or more, such as for a 3D NAND structure. A large area, high aspect ratio opening 203 is disposed above and adjacent to portions of the multilayer stack 201.

In some embodiments, the conductive layers 220 disposed in the dielectric material 210 of the multilayer stack 201 may be composed of tungsten, platinum, titanium, ruthenium, silicon, molybdenum, cobalt and hafnium. Each of the memory openings 215 can be filled using any method known in the industry, such as PECVD or ALD.

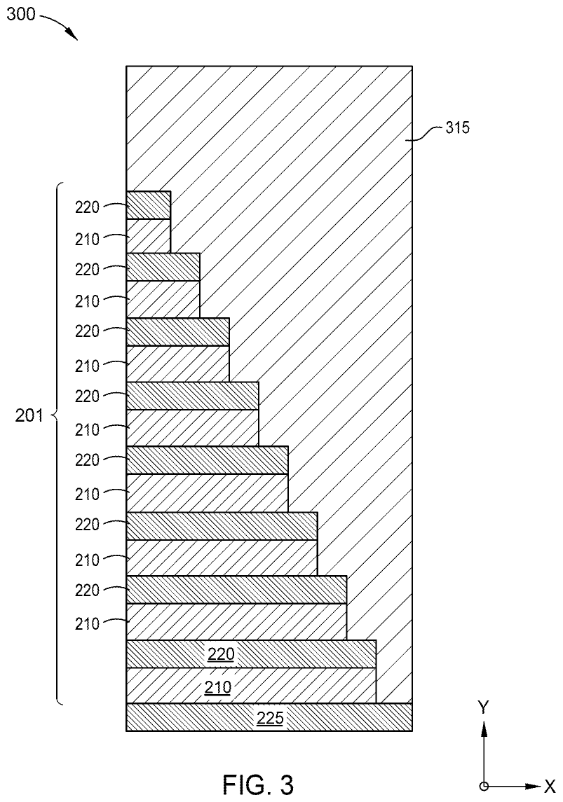

FIG. 3 depicts a first view (e.g., on an X-Y plane) of a memory device 300 having a staircase structure after a gap fill material 315 is deposited into the high aspect ratio opening, according to some embodiments described herein.

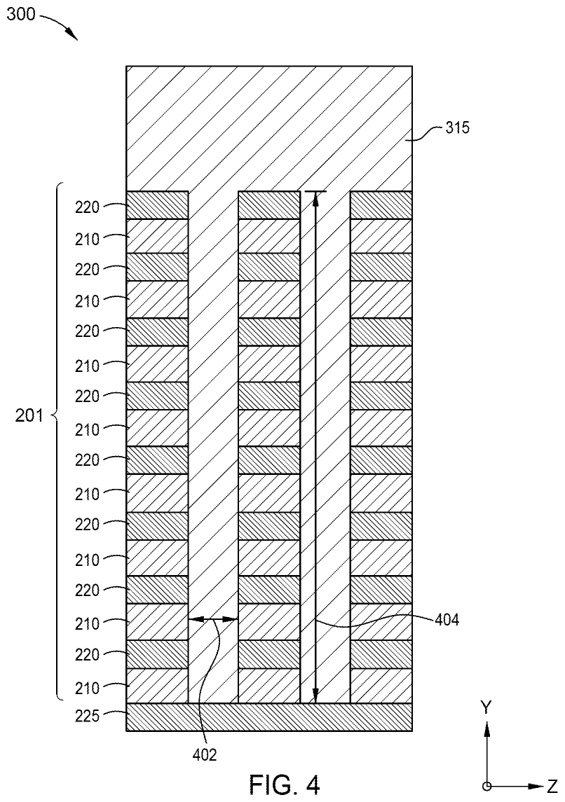

FIG. 4 depicts a second view (e.g., on a Y-Z plane) of the memory device 300 after a gap fill material 315 is deposited into the high aspect ratio opening 203. As used herein, the term “high aspect ratio opening” refers to an opening having a maximum depth 404 to minimum width 402 ratio of about 2:1 or greater, such about 10:1 or greater, such as about 20:1 or greater, such as about 30:1 to about 1000:1 such as about 200:1 to about 500:1. In some embodiments, the high aspect ratio opening has a width of about 1 μm to about 2 μm and a depth of about 10 μm to about 12 μm.

In some embodiments, the gap fill material 315 includes one or more of silicon oxide (SiO), silicon nitride (SiN), silicon carbide (SiC), silicon oxynitride (SiON), silicon oxycarbide (SiOC). The gap fill material 315 is substantially free of voids and seams. The silicon-containing gap fill material 315 can have good compressive properties, high conformality, and low shrinkage. The stress can be about 200 MPa to about 350 MPa, such as about 225 MPa to about 325 MPa.

In some embodiments, the silicon-containing gap fill process 100 described herein enables depositing a silicon-containing gap fill material 315 to a thickness of about 800 nm using about 3000 cycles to about 4000 cycles. As used herein, a growth per cycle refers to a thickness deposited per cycle of operations 102, optional 104, 106, and optional 108. In some embodiments, the growth per cycle for a first duration is larger than a grown per cycle for a second duration after the first duration. In some embodiments, the precursor rate, gas ratios, or a combination thereof are adjusted to adjust growth per each cycle.

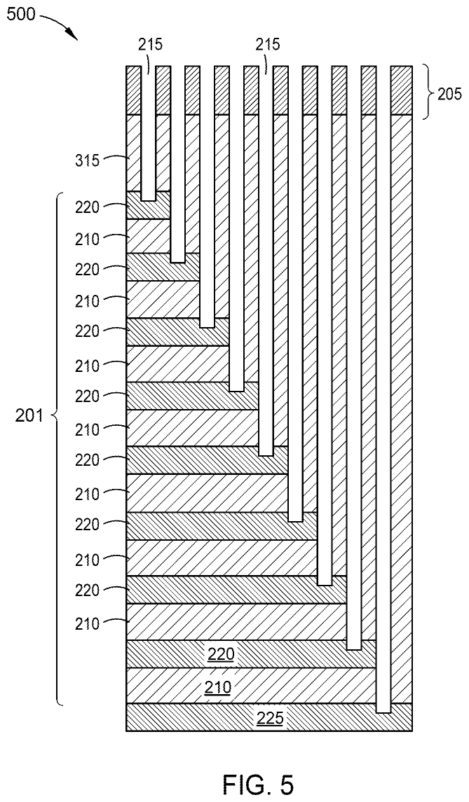

FIG. 5 depicts a memory device 500 having a staircase structure, a gap fill material 315, and memory openings 215, according to some embodiments described herein. A mask layer 205 includes a pre-etching pattern that is formed based on predetermined specifications by use of lithography and mask etch process. The patterned mask layer 205 guides the formation of the features, such as memory openings 215 through the gap fill material 315. The multilayer stack 201 includes multiple conductive layers 220, and the conductive layers 220 formed a staggered arrangement so that each of the memory openings 215 reaches each of the conductive layers 220 that are positioned at different depths (Z-direction depicted in FIG. 4) within the multilayer stack 201. Each of the memory openings 215 are formed using a plasma etching process, in accordance with the pattern formed in the mask layer 205 and have a different depth and contact a different conductive layer 220. Each of the memory openings 215 formed during the plasma etching process also do not extend through the corresponding conductive layer 220. In some embodiments, the memory openings 215 are formed using a fluorocarbon radical plasma etch process. Although not depicted in the figures, the memory openings 215 can be filled with conductive materials to form connections, such as copper, tungsten, or combinations thereof. The connections are substantially free of cracks and defects.

In some embodiments, diaminosilane and/or aminosilane precursors are delivered to the high aspect ratio openings 203. The diaminosilane and/or aminosilane precursors can be co-reacted with an oxygen containing gas, such as ozone, peroxide, oxygen-containing plasma, or combinations thereof. In some embodiments, the precursor includes a component having the formula R₂—Si—Si—R₂, where each R is independently a group including a carbon-containing group, a hydrogen-containing group, an oxygen-containing group, a nitrogen-containing group, a silicon-containing group, or combinations thereof. In some embodiments, one or more R independently includes an isopropyl group, a butyl group, an amine group, or combinations thereof. In some embodiments, the precursor includes silane, disilane, trisilane, tetrasilane, and combinations thereof. In some embodiments, one or more R independently include an isopropylamine group and a silane group, such as N-isopropyltrisilan-1-amine having the structure depicted by Formula I.

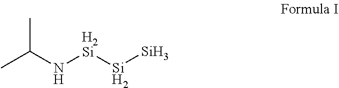

In some embodiments, one or more R groups independently includes diisopropylamino groups, such as 1,2-Bis(diisopropylamino)disilane (e.g., BDIPADS).

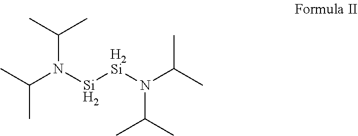

Without being bound by theory, it is believed that additional silicon atoms, such as two, three or four silicon atoms in the precursor enables enhanced growth per cycle by increasing reactivity of the precursor. A reduced amount of precursor is used to deposit the film due to the additional molar concentration of silicon on in the molecule of the precursor.

In some embodiments, the precursor includes a compound having the formula (R₃Si)₃N, where each R is independently a group including a carbon-containing group, a hydrogen-containing group, an oxygen-containing group, a nitrogen-containing group, a silicon-containing group, or combinations thereof. In some embodiments, each R independently includes a propyl group, an isopropyl group, a butyl group, an amine group, or combinations thereof. In some embodiments, the precursor includes tris(trialkylsilyl)amine, such as tris(trimethylsilyl)amine, trisilylamine, or combinations thereof.

In some embodiments, the precursor includes a component having the formula SiR₄, where each R is independently a group including a carbon-containing group, a hydrogen-containing group, an oxygen-containing group, a nitrogen-containing group, a silicon-containing group, or combinations thereof. In some embodiments, each R independently includes a hydrogen, a propyl group, an isopropyl group, a butyl group, an amine group, or combinations thereof. In some embodiments, the precursor includes tetraethyl orthosilicate (TEOS) (e.g., tetraethyl silicate), silane, disilane, trisilane, tetrasilane, or combinations thereof.

In some embodiments, the precursor includes a component having the formula R₂Si—NR₂, such as a silylamine, where each R is independently a group including a carbon-containing group, such as a branched or linear group, a hydrogen-containing group, an oxygen-containing group, a nitrogen-containing group, a silicon-containing group, or combinations thereof. In some embodiments, one or more R independently includes a hydrogen, a propyl group, an isopropyl group, a butyl group, an amine group, or combinations thereof. In some embodiments, the precursor includes one or more of the following compounds N-isopropyltrisilan-1-amine, N-isopropyl-N′,N′-disilylsilanediamine, 1,1,-dimethoxy-N,N,N′N′-tetramethylsilanediamine, 1,1,-diethoxy-N, N, N′, N′-tetramethylsilanediamine, N,N-dimethylsilanamine, N,N-diethylsilanamine, N,N-dipropylsilanamine, N,N-diisopropylsilanamine, N,N-dibutylsilanamine, N,N-di-tert-butylsilanamine, tetramethylsilanediamine, N,N,N′,N′-tetraethylsilanediamine, N,N,N′,N′-tetraisopropylsilanediamine, N,N,N′N-tetrapropylsilanediamine, N,N,N′,N′-tetrabutylsilanediamine, N,N,N′N′-tetra-tert-butylsilanediamine In some embodiments, the precursor includes N,N-di-sec-butylsilanamine, N,N′-dimethylsilanediamine, N,N′-diethylsilanediamine, N,N′-dibutylsilanediamine, N,N′-dipropylsilanediamine, N,N′-diisopropylsilanediamine, N,N′-di-tert-butylsilanediamine, hexaethylsilanetriamine, N,N,N′N′N″,N″-hexaisopropylsilanetriamine, hexapropylsilanetriamine, N″,N″-hexamethylsilanetriamine, hexabutlsilanetriamine, N,N,N′,N′N″,N″-hexa-tert-butylsilanetriamine, tripropylsilanetriamine, N,N′,N″-tributylsilanetriamine, N,N′,N″-triethylsilanetriamine, N,N′,N″-triisopropylsilanetriamine, N,N′,N″-tri-tert-butylsilanetriamine, N,N′,N″-trimethylsilanetriamine, N,N,N′,N′,N″,N″,N′″,N′″-octamethylsilanetetraamine, N,N,N′,N′,N″,N″,N′″,N′″-octaisopropylsilanetetraamine, N,N,N′,N′,N″,N″,N′″,N′″-octa-tert-butylsilanetetraamine, N,N,N′,N′,N″,N″,N′″,N′″-octapropylsilanetetraamine, N,N′,N′,N′″,N′″-tetraethylsilanetetraamine, N,N,N′,N′,N″,N″,N′″,N′″-octabutylsilanetetraamine, N,N′,N″,N′″-tetra-tert-butylsilanetetraamine, N,N,N′,N′,N″,N″,N′″,N′″-octaethylsilanetetraamine, N,N′,N″,N″-tetramethylsilanetetraamine, N,N′,N″,N′″-tetraisopropylsilanetetraamine, N,N′,N″,N′″-tetrapropylsilanetetraamine, and N,N′,N″,N″-tetrabutylsilanetetraamine. In some embodiments, the precursor includes a compound N,N-di-sec-butylsilanamine having the structure depicted in Formula III.

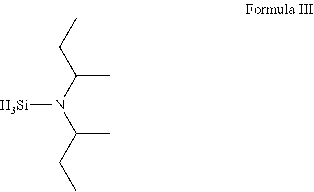

The methods and precursor chemistry described herein enable large area gap fill for 3D NAND devices. The deposited large area gap fill material includes a compressive silicon-containing film that is substantially free of voids and seams. The compressive property of the film can be etched to form openings that are subsequently filled with conductive material to form connections. The connections are formed within the silicon-containing film without cracking and are substantially free of defects. The method also reduces the amount of precursor that is needed to fill large area gap fill compared with conventional methods.

While the foregoing is directed to embodiments of the present disclosure, other and further embodiments of the disclosure can be devised without departing from the basic scope thereof, and the scope thereof is determined by the claim that follows.

What is claimed is:

1. A method of forming a high aspect ratio structure within a 3D NAND structure, comprising:
delivering a precursor to a high aspect ratio opening disposed within a multilayer stack having two or more alternating layers, the precursor selected from the group consisting of a diaminosilane, an aminosilane, and a combination thereof; and
delivering an oxygen-containing compound to the high aspect ratio opening, wherein the precursor and the oxygen-containing compound are alternated cyclically to fill the high aspect ratio opening.

2. The method of claim 1, wherein the multilayer stack comprises a plurality of conductive layers alternated with a plurality of dielectric layers.

3. The method of claim 1, wherein the precursor comprises a compound having a structure:

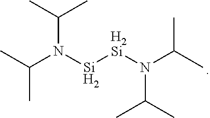

4. The method of claim 1, wherein the precursor comprises a compound having the structure:

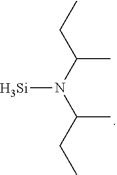

5. The method of claim 1, wherein the precursor further comprises a component having a formula R₂—Si—Si—R₂, wherein each R is independently a group including a carbon-containing group, a hydrogen-containing group, an oxygen-containing group, a nitrogen-containing group, a silicon-containing group, or combinations thereof.

6. The method of claim 1, wherein the precursor further comprises a component having the formula R₂—Si—Si—R₂, wherein one or more R independently includes an isopropyl group, a butyl group, an amine group, or combinations thereof.

7. The method of claim 1, wherein the precursor further comprises silane, disilane, trisilane, tetrasilane, and combinations thereof.

8. The method of claim 1, wherein a ratio of the high aspect ratio openings is about or greater.

9. The method of claim 1, wherein filling the high aspect ratio opening further comprises forming a silicon-containing material selected the group consisting of silicon germanium (SiGe), silicon oxide (SiO), silicon nitride (SiN), silicon carbide (SiC), silicon oxynitride (SiON), silicon oxycarbide (SiOC), and combinations thereof.

10. The method of claim 1, wherein the oxygen-containing compound is selected from the group consisting of O₃ (e.g., ozone), H₂O₂ (e.g., peroxide), oxygen plasma, and combinations thereof.

11. A method of forming a 3D NAND structure, comprising:
delivering a precursor to a high aspect ratio opening disposed within a multilayer stack having two or more alternating layers, the precursor selected from the group consisting of a diaminosilane, an aminosilane, and a combination thereof; and
delivering an oxygen-containing plasma to the high aspect ratio opening, wherein the precursor and the oxygen-containing plasma are alternated cyclically to fill the high aspect ratio opening with a silicon-containing material; and
etching an opening within the silicon-containing material.

12. The method of claim 11, wherein the oxygen-containing plasma is pulsed for about 2 seconds to about 10 seconds.

13. The method of claim 11, wherein a time pulse ratio of precursor to oxygen-containing plasma is about 1:20 to about 1:5.

14. The method of claim 11, wherein the oxygen-containing plasma is provided from a remote plasma source coupled to a power source to energize gas delivered to the remote plasma source at a power of about 100 W to about 300 W and a frequency of about 13 MHz to about 60 MHz.

15. The method of claim 11, wherein etching the opening within the silicon-containing material comprises a fluorocarbon radical plasma etch process.

16. A method of forming a 3D NAND structure on a substrate, comprising:
delivering a precursor to a high aspect ratio opening disposed within a multilayer stack having two or more alternating layers, the precursor comprises a diaminosilane; and
delivering an oxygen-containing plasma to the high aspect ratio opening, wherein the precursor and the oxygen-containing plasma are alternated cyclically to fill the high aspect ratio opening with a silicon-containing material, the high aspect ratio opening having an aspect ratio of about 10:1 or greater.

17. The method of claim 16, further comprising maintaining a substrate temperature of about 100° C. to about 450° C.

18. The method of claim 16, wherein delivering the precursor and the oxygen-containing plasma is an atomic layer deposition process with a growth per cycle of about 1.5 Å per cycle to about 3 Å per cycle.

19. The method of claim 16, wherein the precursor includes a component having a formula R₂Si—NR₂, wherein each R is independently selected from the group consisting of a carbon-containing group, such as a branched or linear group, a hydrogen-containing group, an oxygen-containing group, a nitrogen-containing group, a silicon-containing group, and combinations thereof.

20. A memory device, comprising:
a multilayer stack comprising a plurality of conductive layers alternated with a plurality of dielectric layers;
a gap fill material disposed over and at least partially adjacent to the multilayer stack, the gap fill material having one or more of:
a stress of about 200 MPa to about 350 MPa;
a conformality of about 98% to about 99%;
a shrinkage property of about 0.01% to about 10%; and
a plurality of conductive connections disposed within the gap fill material.
